(19) United States
(12) Patent Application Publication
(10) Pub. No.: US 2026/0312574 A1
(43) Pub. Date: Oct. 8, 2026

(54) HIGH-VOLTAGE PULSE GENERATION CIRCUIT

(71) Applicant: SANSHA ELECTRIC MANUFACTURING CO., LTD., Osaka (JP)

(72) Inventors: Koki AIDA, Osaka-shi (JP); Kazuhiro NISHIKAWA, Osaka-shi (JP); Kenzo DANJO, Osaka-shi (JP)

(21) Appl. No.: 19/532,797

(22) Filed: Feb. 6, 2026

(30) Foreign Application Priority Data
Apr. 7, 2025 (JP) 2025-063119

(51) Int. Cl. H03K 3/57; H03K 3/011

(52) U.S. Cl. CPC H03K 3/57; H03K 3/011

(57) ABSTRACT

A high-voltage pulse generation circuit according to the present disclosure includes a direct-current power supply for outputting a direct-current voltage, a transformer including a primary winding having one end connected to a positive terminal of the direct-current power supply, an energy storage inductor connected across both ends of the primary winding of the transformer, a switching element that includes one main terminal connected to another end of the primary winding of the transformer and includes another main terminal connected to a negative terminal of the direct-current power supply, an external capacitor connected across both ends of the switching element, across the both ends of the primary winding, or across the both ends of the switching element and the both ends of the primary winding, and a control circuit configured to keep the switching element in conduction for a predetermined time and then bring the switching element into a cut-off state.

### BACKGROUND OF THE INVENTION

This application claims the benefit of foreign priority to Japanese Patent Application No. 2025-063119, field Apr. 7, 2025, which is incorporated by reference in its entirety.

### FIELD OF THE INVENTION

The present invention relates to a high-voltage pulse generation circuit.

### DESCRIPTION OF RELATED ART

As a high-voltage pulse generation circuit, an inductive energy storage circuit is known. In this system, energy is stored in an inductor by passing a current through the inductor, and a high-voltage pulse is obtained by rapidly cutting off the current. For example, in a high-voltage generation circuit described in JP 2009-165201 A (see FIG. 2), a transformer and a switch are connected in series to both ends of a direct-current power supply, and a load is connected to the secondary side of the transformer. In this high-voltage generation circuit, when the switch is closed, a current flows through an inductor that is the primary winding of the transformer, and thus inductive energy is stored in the primary winding. When a predetermined amount of inductive energy is stored, the switch is opened, and thus the primary current is cut off and a high-voltage pulse is generated across the secondary winding.

### SUMMARY OF THE INVENTION

The conventional high-voltage pulse generation circuit has a problem that the release rate of the stored energy is slow because of a large inductance of the secondary winding of the transformer, and that a high-voltage peak cannot be obtained because of a load capacitance component or the like at the time of energy release.

The present invention has been made to solve the above-described problem, and an object of the present invention is to provide a high-voltage pulse generation circuit capable of achieving a high release rate of stored energy and obtaining a high-voltage peak.

In order to achieve the above object, a high-voltage pulse generation circuit according to an aspect of the present disclosure comprises a direct-current power supply for outputting a direct-current voltage, a transformer including a primary winding having one end connected to a positive terminal of the direct-current power supply, an energy storage inductor connected across both ends of the primary winding of the transformer, a switching element including one main terminal connected to another end of the primary winding of the transformer, the switching element including another main terminal connected to a negative terminal of the direct-current power supply, an external capacitor connected across both ends of the switching element, connected across the both ends of the primary winding, or connected across the both ends of the switching element and across the both ends of the primary winding, and a control circuit configured to keep the switching element in conduction for a predetermined time and then bring the switching element into a cut-off state.

The present disclosure has an effect of providing a high-voltage pulse generation circuit capable of achieving a high release rate of stored energy and obtaining a high-voltage peak.

### BRIEF DESCRIPTION OF THE DRAWINGS

FIG. 1 is a circuit diagram illustrating an example of a configuration of a high-voltage pulse generation circuit according to a first embodiment of the present disclosure;

FIG. 2 is a waveform diagram illustrating waveforms of a digital control signal of a switching element in FIG. 1;

FIG. 3 is a waveform diagram illustrating waveforms of high-voltage pulses output from a secondary winding of a transformer in FIG. 1;

FIG. 4 is a schematic diagram illustrating a current on a primary side of the high-voltage pulse generation circuit in FIG. 1;

FIG. 5 is a graph showing a voltage and a current in the high-voltage pulse generation circuit in FIG. 1;

FIG. 6 is a circuit diagram illustrating a circuit configuration in Simulation 1, for the high-voltage pulse generation circuit of the first embodiment, for observation of a change in the output voltage in the case of changing the inductance of an energy storage inductor;

FIG. 7 is a graph showing results of Simulation 1;

FIG. 8 is a circuit diagram illustrating a circuit configuration in Simulation 2, for the high-voltage pulse generation circuit of the first embodiment, for observation of a change in the output voltage in the case of changing the capacitance of an external capacitor;

FIG. 9 is a graph showing results of Simulation 2;

FIG. 10 is a circuit diagram illustrating a circuit configuration in Simulation 3, for the high-voltage pulse generation circuit of the first embodiment, for observation of a change in the output voltage in the case of changing the load capacitance without the external capacitor;

FIG. 11 is a circuit diagram illustrating a circuit configuration in Simulation 3 for observation of a change in the output voltage in a case where, in the high-voltage pulse generation circuit of the first embodiment, the load capacitance is changed with the external capacitor;

FIG. 12 is a graph showing a change in the output voltage with respect to a change in the load capacitance in Simulation 3;

FIG. 13 is a graph showing a change in the pulse width with respect to a change in the output voltage in Simulation 3;

FIG. 14 is a graph showing changes in an output voltage Vout, a drain-source voltage Vds of the switching element, and a composite current Ix in a case where, in Simulation 3, the external capacitor has a capacitance of 2000 pF and the load capacitance is 10 pF;

FIG. 15 is a circuit diagram illustrating an example of the high-voltage pulse generation circuit of the first embodiment;

FIG. 16 is a graph showing the output voltage Vout and a secondary-side current Is of the high-voltage pulse generation circuit in the example of FIG. 15;

FIG. 17 is a circuit diagram illustrating an example of a configuration of a high-voltage pulse generation circuit according to a second embodiment of the present disclosure; and

FIG. 18 is a circuit diagram illustrating an example of a configuration of a high-voltage pulse generation circuit according to a third embodiment of the present disclosure.

### DETAILED DESCRIPTION OF EMBODIMENTS

A high-voltage pulse generation circuit according to an aspect of the present disclosure includes a direct-current power supply for outputting a direct-current voltage, a transformer including a primary winding having one end connected to a positive terminal of the direct-current power supply, an energy storage inductor connected across both ends of the primary winding of the transformer, a switching element including one main terminal connected to another end of the primary winding of the transformer, the switching element including another main terminal connected to a negative terminal of the direct-current power supply, an external capacitor connected across both ends of the switching element, connected across both ends of the primary winding, or connected across both ends of the switching element and across both ends of the primary winding, and a control circuit configured to keep the switching element in conduction for a predetermined time and then bring the switching element into a cut-off state.

According to this configuration, when the control circuit keeps the switching element in conduction for a predetermined time and then brings the switching element into a cut-off state, inductive energy (magnetic energy) is stored in the energy storage inductor while the switching element is kept in a conductive state. Then, when the switching element is brought into a cut-off state, the direct-current voltage of the direct-current power supply is applied to the energy storage inductor and the parasitic capacitances of the external capacitor and the switching element, and thus LC resonance occurs, and a sinusoidal pulse voltage (see FIG. 5) is generated at both ends of the parasitic capacitances of the external capacitor and the switching element. The sinusoidal pulse voltage is applied to the primary winding of the transformer, and a secondary winding of the transformer outputs a sinusoidal pulse voltage corresponding to the turns ratio.

In this process, the transformer mainly functions as an element that is nearly an ideal transformer rather than as an element that stores the inductive energy, so that even if the secondary winding has a large inductance, the inductance does not inhibit the release rate of the energy stored in the external capacitor. Furthermore, the peak of the pulsed voltage output from the secondary winding of the transformer can be increased by using the resonance of the energy storage inductor with the external capacitor and the load capacitance. As a result, a high-voltage pulse generation circuit can be provided that is capable of achieving a high release rate of stored energy and obtaining a high-voltage peak.

The control circuit may be configured to input a digital control signal, to a control terminal of the switching element, including a predetermined pulse to keep the switching element in conduction for a predetermined time and then bring the switching element into a cut-off state.

A digital signal is a rectangular wave signal and includes a rectangular pulse, and therefore according to this configuration, a rectangular pulse having a width set to a predetermined time is set as a predetermined pulse, and thus the switching element can be kept in conduction for a predetermined time and then brought into a cut-off state.

The control circuit may be configured to input the digital control signal, to the control terminal of the switching element, including a plurality of the predetermined pulses at a predetermined time interval.

According to the configuration, the switching element is kept in conduction for a predetermined time and then brought into a cut-off state at a predetermined time interval, and thus a voltage pulse having a high voltage peak can be output at the predetermined time interval.

The energy storage inductor may have an inductance of 1/7 or less of the inductance of the primary winding of the transformer.

According to this configuration, a high-voltage pulse can be generated that has a high voltage peak with respect to the inductance of the energy storage inductor.

The energy storage inductor may have an inductance of 1/10 or less of the inductance of the primary winding of the transformer.

According to this configuration, a high-voltage pulse can be generated that has a higher voltage peak with respect to the inductance of the energy storage inductor.

The energy storage inductor may have an inductance of 1 μH or more and 4 μH or less.

According to this configuration, a high-voltage pulse can be generated that has a high voltage peak with respect to the inductance of the energy storage inductor.

The external capacitor may have a capacitance of more than 0 pF and 2000 pF or less.

According to this configuration, a high-voltage pulse can be generated that has a high voltage peak with respect to the capacitance of the external capacitor.

Hereinafter, specific embodiments of the present disclosure will be described with reference to the drawings. In the following description, the same or corresponding elements are denoted by the same reference signs throughout all the drawings, and redundant description of the elements will be omitted. The drawings described below are for describing the present disclosure, and therefore in the drawings, an element unrelated to the present disclosure may be omitted, a dimension may be inaccurate for exaggeration or the like, simplification may be performed, or the forms of elements corresponding to each other may be inconsistent in a plurality of drawings. The present disclosure is not limited to the following embodiments.

### Definitions

In the specification and claims of the present application, “connecting” elements included in an electric circuit implies “mechanically connecting” and “electrically connecting” the elements.

### First Embodiment

### [Configuration]

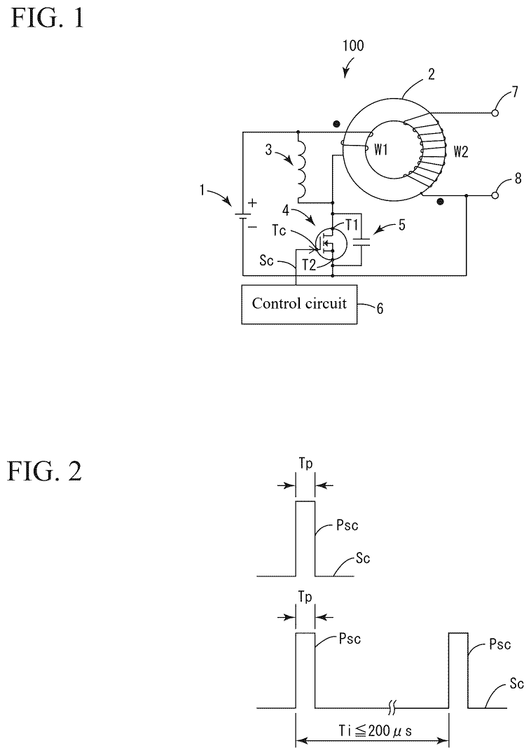

FIG. 1 is a circuit diagram illustrating an example of a configuration of a high-voltage pulse generation circuit 100 according to a first embodiment of the present disclosure. Referring to FIG. 1, the high-voltage pulse generation circuit 100 includes a direct-current power supply 1, a transformer 2, an energy storage inductor 3, a switching element 4, an external capacitor 5, and a control circuit 6. Hereinafter, these elements will be described in detail.

### <Direct-Current Power Supply 1>

The direct-current power supply 1 outputs a direct-current voltage between the positive terminal and the negative terminal. The direct-current power supply 1 is not particularly limited as long as it can output a direct-current voltage. Examples of the direct-current power supply 1 include a direct current-direct current converter using commercial power as a power supply, a battery, a cell, and a renewable energy power generation device.

### <Transformer 2>

The transformer 2 includes a primary winding W1 having one end connected to the positive terminal of the direct-current power supply 1, and includes a secondary winding W2 having both ends connected to a positive output terminal 7 and a negative output terminal 8 of the high-voltage pulse generation circuit 100. The negative output terminal 8 is connected to the negative terminal of the direct-current power supply 1.

The transformer 2 is not particularly limited. In a case where the secondary winding outputs a voltage pulse having a high voltage peak, the transformer 2 desirably has high withstand voltage performance. The turns ratio n of the transformer 2 is not particularly limited. However, in order to generate a voltage pulse having a high voltage peak, the turns ratio n is preferably 1 or more. In the first embodiment, the turns ratio n is, for example, 5.

### <Energy Storage Inductor 3>

The energy storage inductor 3 is connected in parallel to the primary winding W1 of the transformer 2. In other words, the energy storage inductor 3 is connected across both ends of the primary winding W1 of the transformer 2.

The energy storage inductor 3 plays a role in storing the inductive energy of the high-voltage pulse generation circuit 100 separately from the primary winding W1 of the transformer 2. Therefore, in the present disclosure, the configuration is first important in which the high-voltage pulse generation circuit 100 includes the energy storage inductor 3. This role can be enhanced as the current flowing through the energy storage inductor 3 is larger than the current of the primary winding W1, of the transformer 2, that is connected in parallel to the energy storage inductor 3 and stores inductive energy similarly to the energy storage inductor 3. In other words, the role of the energy storage inductor 3 can be enhanced as the inductance of the energy storage inductor 3 is smaller than the inductance of the primary winding W1 of the transformer 2.

Therefore, the energy storage inductor 3 preferably has a smaller inductance than the primary winding W1 of the transformer 2. For example, the energy storage inductor 3 more preferably has an inductance as small as the primary conversion leakage inductance of the transformer 2. In the first embodiment, the energy storage inductor 3 still more preferably has an inductance of, for example, 1 to 4 μH (see Simulation 1 described below).

The form of the energy storage inductor 3 is not particularly limited. As the energy storage inductor 3, a commercially available inductor (reactor) can be used. In the first embodiment, the energy storage inductor 3 includes, for example, an air core coil. This is because an air core coil is not magnetically saturated.

### <Switching Element 4>

The switching element 4 includes a first main terminal T1, a second main terminal T2, and a control terminal Tc that brings the first main terminal T1 and the second main terminal T2 into a conductive state or a cut-off state according to the potential difference of the potential of a control signal input with respect to the first main terminal or the second main terminal. The switching element 4 is connected to the other end of the primary winding W1 of the transformer 2 at the first main terminal T1, and is connected to the negative terminal of the direct-current power supply 1 at the second main terminal T2. To the control terminal Tc of the switching element 4, a digital control signal (control signal) Sc is input from the control circuit 6.

Examples of the switching element 4 include a field effect transistor (FET), a bipolar transistor, an insulated gate bipolar transistor (IGBT), and a thyristor. Here, the switching element 4 includes an N-channel metal oxide semiconductor field effect transistor (N-channel MOSFET). In this case, the drain, the source, and the gate of the N-channel MOSFET are the first main terminal T1, the second main terminal T2, and the control terminal Tc, respectively.

### <External Capacitor 5>

The external capacitor 5 is connected across both ends of the switching element 4. The external capacitor 5 may be connected across both ends of the primary winding W1 of the transformer 2, or may be connected across both ends of the switching element 4 and across both ends of the primary winding W1 of the transformer 2. A second embodiment exemplifies a configuration in which the external capacitor 5 is connected across both ends of the primary winding W1 of the transformer 2, and a third embodiment exemplifies a configuration in which the external capacitor 5 is connected across both ends of the switching element 4 and across both ends of the primary winding W1 of the transformer 2.

Even in a case where the external capacitor 5 is connected across both ends of the switching element 4 and across both ends of the primary winding W1 of the transformer 2, electric charge is stored in the external capacitor 5 when the switching element 4 is in a cut-off state, so that a similar effect is obtained although there is a difference between LC series resonance and parallel resonance.

The switching element 4 has a smaller parasitic capacitance than the external capacitor 5. However, in the LC resonance of the parasitic capacitance with the energy storage inductor 3, although a high-voltage pulse having a high voltage peak is generated between the positive output terminal 7 and the negative output terminal 8, the amount of energy that can be input is limited. Therefore, in the case of a large load capacitance, a desired voltage cannot be generated.

In a main application of the high-voltage pulse generation circuit 100, for example, in a welding machine or a discharge lamp, the capacitance between electrodes is large, so that the high-voltage pulse has a low voltage peak.

Therefore, in the present disclosure, the high-voltage pulse generation circuit 100 includes the external capacitor 5 between both ends of the switching element 4 and/or between both ends of the primary winding W1 of the transformer 2. Due to the LC resonance of the external capacitor 5 (and the parasitic capacitance) with the energy storage inductor 3, a high-voltage pulse having a higher voltage peak is generated between the positive output terminal 7 and the negative output terminal 8 than in a case where the external capacitor 5 is not included (see Simulation 2 described below).

The same applies to a case where the external capacitor 5 is not included. The inventor of the present invention has found that a high-voltage pulse having a high voltage peak is generated between the positive output terminal 7 and the negative output terminal 8 due to the LC resonance of the parasitic capacitance and the load capacitance of the switching element 4 with the energy storage inductor 3.

However, it is impossible to identify the parasitic capacitances of various types of the switching elements 4 one by one, and therefore the scope of the present disclosure is limited to a case where the external capacitor 5 is connected across both ends of the primary winding W1 of the transformer 2 and/or across both ends of the switching element 4.

Therefore, in the present disclosure, a configuration is important in which the high-voltage pulse generation circuit 100 includes the external capacitor 5 and/or an external capacitor 14 described below (see Second Embodiment).

The form of the external capacitor 5 is not particularly limited. As the external capacitor 5, a commercially available capacitor can be used.

The external capacitor 5 preferably has a capacitance of more than 0 pF and 2000 pF or less (see Simulations 2 and 3 described below). If the external capacitor 5 has a capacitance within this range, a high-voltage pulse can be generated that has a high voltage peak and a pulse width that are sufficient in main applications.

### <Control Circuit 6>

### {Function}

The control circuit 6 keeps the switching element 4 in conduction for a predetermined time Tp and then brings the switching element 4 into a cut-off state. Specifically, the control circuit 6 generates a digital control signal (control signal) Sc including a predetermined pulse Psc to keep the switching element 4 in conduction for the predetermined time Tp and then bring the switching element 4 into a cut-off state, and inputs the digital control signal Sc to the control terminal Tc of the switching element 4.

FIG. 2 is a waveform diagram illustrating waveforms of the digital control signal Sc of the switching element 4. Referring to FIG. 2, the digital control signal Sc includes a single rectangular pulse as the predetermined pulse Psc as illustrated in the upper part of FIG. 2. In the digital control signal Sc, the signal level at the lower end (starting end of the rise) of the rectangular pulse represents the low level of the binary signal (digital control signal), and the signal level at the upper end (termination of the rise) of the rectangular pulse represents the high level of the binary signal (digital control signal). The high level is set to the level of a voltage higher than the threshold voltage of the N-channel MOSFET included in the switching element 4. The pulse width of the predetermined pulse Psc (rectangular pulse) is set to the predetermined time Tp. The predetermined time Tp is set to, for example, 2 μs. Thus, when the digital control signal Sc is input to the control terminal Tc of the switching element 4, the switching element 4 is brought into a conductive state for the predetermined time Tp from a cut-off state. Then, when the predetermined time Tp elapses, the switching element 4 is brought into a cut-off state. Thus, a high-voltage pulse (pulsed output voltage Vout having a high-voltage peak) is generated in the secondary winding W2 of the transformer 2.

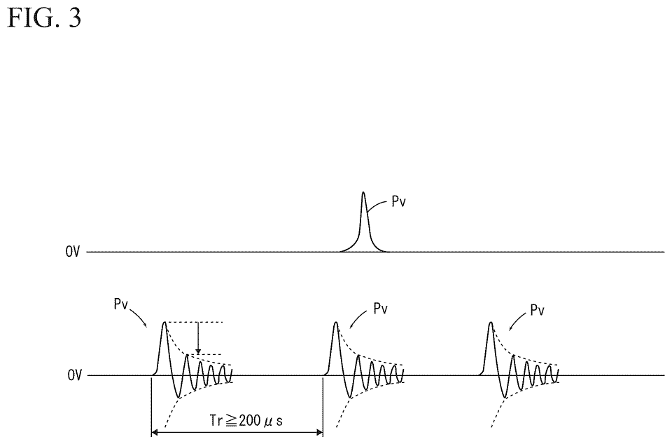

As illustrated in the lower part of FIG. 2, the control circuit 6 may generate the digital control signal Sc including a plurality of single rectangular pulses that are the predetermined pulses Psc, at a predetermined time interval Ti. The predetermined time interval Ti is set to, for example, 200 μs or more. Thus, in a device utilizing a high voltage pulse, in a case where an object cannot be achieved by the first high-voltage pulse Pv (see FIG. 3), the object can be achieved by a subsequent high-voltage pulse Pv.

### {Configuration}

The configuration of the control circuit 6, which can be configured by a known circuit, will be briefly described. The control circuit 6 includes a control unit and a drive unit.

The control unit generates a binary signal, as a voltage command, having a rectangular waveform corresponding to the digital control signal Sc illustrated in FIG. 2. The control unit includes, for example, an arithmetic unit including a processor and a memory. The memory of the arithmetic unit stores a predetermined program for generation of the voltage command, the processor reads and executes the predetermined program, and thus the control unit is realized as a functional block that generates the voltage command. In this case, the arithmetic unit operates as the control unit. The arithmetic unit can include, for example, a computer, a personal computer, a microcontroller, a micro processing unit (MPU), a field programmable gate array (FPGA), or a programmable logic controller (PLC).

Here, the functions of the elements disclosed herein can be executed using circuitry or processing circuitry including a generic processor, a special purpose processor, an integrated circuit, an application specific integrated circuit (ASIC), a conventional circuit, and/or a combination thereof configured or programmed to execute the disclosed functions. A processor includes a transistor and another circuit, and therefore is considered to be a processing circuit or circuit. In the present disclosure, the term “circuit” or “unit” refers to hardware that executes recited functions or hardware programmed to execute recited functions. The hardware may be the hardware disclosed herein, or may be any other known hardware that is programmed or configured to execute the recited functions. In a case where the hardware is a processor considered to be a circuit, the term “circuit” or “unit” refers to a combination of hardware and software, and the software is used for configuration of the hardware and/or the processor.

The drive unit generates the digital control signal Sc according to the voltage command generated by the control unit. Specifically, the control unit includes, for example, a switching element. When the voltage command is input to the control terminal, the switching element is turned on and off according to the binary signal of the voltage command to generate the digital control signal Sc having a rectangular waveform corresponding to the binary signal of the voltage command.

### {Others}

The control circuit 6 never generates a control signal formed by a direct-current voltage having a voltage amplitude varying sinusoidally at the LC resonance frequency of the high-voltage pulse generation circuit 100. The reason is as follows.

As described above, in the high-voltage pulse generation circuit 100, the voltage generated by the LC resonance of the energy storage inductor 3 on the primary side of the transformer 2 with the external capacitor 5 becomes a high voltage corresponding to the turns ratio of the transformer 2 and is generated on the secondary side. Therefore, the control circuit 6 is only required to generate a rectangular wave control signal as illustrated in FIG. 2. If a control signal of the sine wave generated using the LC resonance is input from the control circuit 6 to the switching element 4, the control signal is superimposed on the resonance phenomenon by the energy storage inductor 3 and the external capacitor 5, so that the control is complicated, and a desired high-voltage pulse is difficult to generate between the positive output terminal 7 and the negative output terminal 8 on the secondary side of the transformer 2.

As described above, the control circuit 6 never generates a sinusoidal control signal using the LC resonance phenomenon.

The high-voltage pulse generation circuit 100 is not intended to supply a low-voltage and high-current energy source, and is not intended to generate intentional sinusoidal LC resonance in the secondary winding of the transformer 2 and supply a high-current energy source at a constant frequency, a constant voltage, and a high frequency assuming a low-impedance load.

### [Operation]

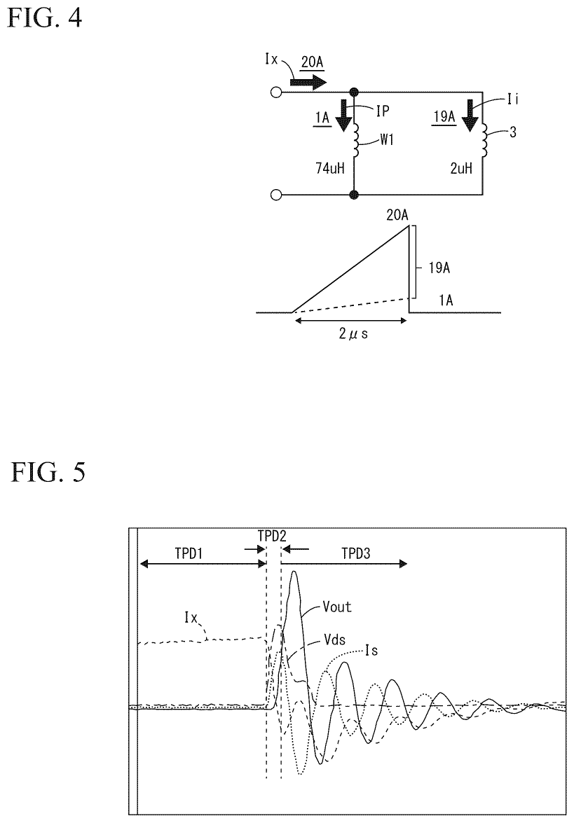

Next, the operation of the high-voltage pulse generation circuit 100 configured as described above will be described with reference to FIG. 1 to FIG. 5. FIG. 3 is a waveform diagram illustrating waveforms of high-voltage pulses output from the secondary winding of the transformer 2 in FIG. 1. FIG. 4 is a schematic diagram illustrating a current on the primary side of the high-voltage pulse generation circuit 100 in FIG. 1. FIG. 5 is a graph showing a voltage and a current in the high-voltage pulse generation circuit 100 in FIG. 1.

First, the definition of the term “high-voltage pulse” will be described. Referring to FIG. 3, in the specification and claims of the present application, the term “high-voltage pulse” refers to both the single high-voltage pulse Pv illustrated in the upper diagram and the high-voltage pulse Pv including a damped wave packet illustrated in the lower diagram. In the high-voltage pulse Pv including a damped wave packet, the peak value of the second wave is 50% or less of the peak value of the first wave as indicated by an arrow. In a case where the high-voltage pulse Pv including a damped wave packet is repeated, the repetition time interval (repetition period) Tr is 200 μs or more.

Referring to FIG. 1, the direct-current power supply 1 outputs an input voltage V1. It is assumed that the input voltage V1 is 19 V. When the control circuit 6 inputs the digital control signal Sc to the control terminal Tc of the switching element 4, the switching element 4 is brought into a conductive state for the predetermined time Tp.

The predetermined time Tp is, for example, 2 μs.

As a result, as illustrated in the upper diagram in FIG. 4, a composite current Ix flows due to the difference between the inductance of the energy storage inductor 3 and the inductance of the primary winding W1 of the transformer 2. The composite current Ix is divided into a current Ip flowing through the primary winding W1 of the transformer 2 and a current Ii flowing through the energy storage inductor 3, and the current Ip and the current Ii are confluent at the first main terminal T1 of the switching element 4 to become the composite current Ix.

Here, it is assumed that the inductance of the primary winding W1 of the transformer 2 is 74 μH and the inductance of the energy storage inductor 3 is 2 μH. Then, as illustrated in the lower diagram in FIG. 4, the composite current Ix linearly increases from 0 A to 20 A during 2 μs, which is the predetermined time Tp, and falls to 0 A after 2 μs elapses. In a case where the composite current Ix is 20 A, the current Ip flowing through the primary winding W1 of the transformer 2 is 1 A, and the current Ii flowing through the energy storage inductor 3 is 19 A.

Next, the operation of the high-voltage pulse generation circuit 100 after the time when the predetermined time Tp ends will be described with reference to FIG. 5. It is assumed that a load capacitance Co (see FIG. 15) is connected (exists) between the positive output terminal 7 and the negative output terminal 8. In FIG. 5, the reference sign Ix denotes the composite current flowing through the primary side of the transformer 2 as described above. The reference sign Is denotes the current of the secondary winding W2 of the transformer 2 (hereinafter, sometimes referred to as “secondary-side current”). The reference sign Vds denotes the drain-source voltage of the switching element 4, and hereinafter, may refer to the voltage across both ends of the external capacitor 5, for convenience. The reference sign Vout denotes the voltage across both ends of the secondary winding of the transformer, that is, the output voltage of the high-voltage pulse generation circuit 100 output from between the positive output terminal 7 and the negative output terminal 8. The reference signs TPD1 to TPD3 denote time intervals in a time series of the operation of the high-voltage pulse generation circuit 100. The reference sign TPD1 denotes the time interval from the rise to immediately before the fall of the composite current Ix, the reference sign TPD2 denotes the time interval during which the composite current Ix falls, and the reference sign TPD3 denotes the time interval after the fall of the composite current Ix.

In the time interval TPD1, as described above, the composite current Ix increases linearly, and thus a predetermined inductive energy is stored in the energy storage inductor 3 (and the primary winding W1 of the transformer 2). Both ends of the external capacitor 5 are substantially short-circuited by the switching element 4, and thus a voltage Vds across both ends of the external capacitor 5 is substantially 0 V.

In the time interval TPD2, the switching element 4 is brought into a cut-off state after the predetermined time Tp elapses. At this time, in a transient state until the switching element 4 is completely brought into a cut-off state, LC resonance occurs simultaneously with the fall of the composite current Ix. The LC resonance is caused by the energy storage inductor 3 and the primary winding W1 of the transformer 2, and the external capacitor 5 and parasitic capacitances of the switching element 4. Thus, a sinusoidal pulse voltage is generated as the drain-source voltage Vds at both ends of the switching element 4 (both ends of the external capacitor 5).

The sinusoidal pulse voltage is applied to the primary winding W1 of the transformer 2. In the secondary winding W2 of the transformer 2, the output voltage Vout corresponding to the turns ratio n appears as a sinusoidal high-voltage pulse having a peak voltage of about 6 kV.

In the time interval TPD3, the high-voltage pulse of the output voltage Vout is consumed by the winding resistance on the secondary side of the transformer 2, the inter-winding parasitic capacitance, the core iron loss, and the like, and is damped to 0 V while vibrating by LC resonance of the high-voltage pulse generation circuit 100. The secondary-side current Is transitions in a pulse damped wave form corresponding to the output voltage Vout from the start of the time interval TPD2. The composite current Ix flows in the reverse direction so as to be damped to 0 A while vibrating.

Thus, the inductive energy stored in the energy storage inductor 3 generates a high-voltage pulse having a high voltage peak in the output voltage Vout.

### [Simulation]

Next, a simulation of the high-voltage pulse generation circuit 100 of the first embodiment will be described. The high-voltage pulse generation circuit 100 in this simulation generates a drain-source voltage (voltage across both ends of the external capacitor 5) Vds of 1.2 kV at both ends of the switching element 4 using LC resonance even if the input voltage is a low voltage (several 10 V), boosts the drain-source voltage Vds by 5 times (times of the turns ratio n) using the transformer 2, and outputs an output voltage Vout of about 6 kV.

### <<Simulation 1>>

First, Simulation 1 will be described for examination of a suitable inductance of the energy storage inductor 3.

### <Circuit>

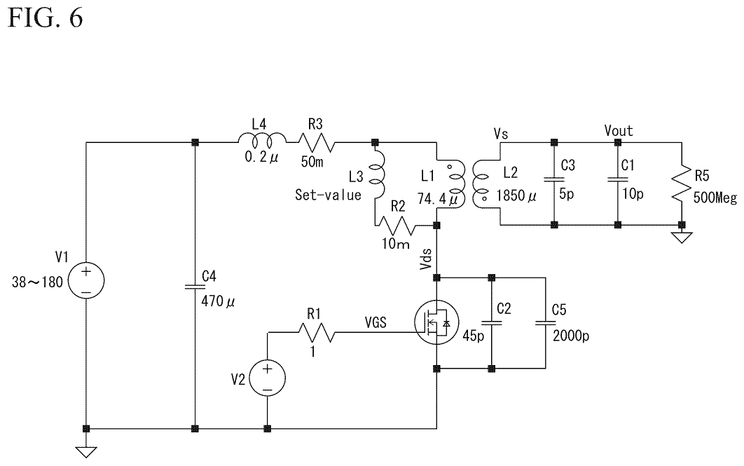

FIG. 6 is a circuit diagram illustrating a circuit configuration in Simulation 1, for the high-voltage pulse generation circuit 100 of the first embodiment, for observation of a change in the output voltage Vout in the case of changing the inductance of the energy storage inductor 3. In this circuit diagram, a symbol attached to a circuit element represents the voltage, the resistance, the inductance, or the capacitance, and the number represents its value.

Referring to FIG. 6, in the circuit of Simulation 1, the value “Set-value” of an inductance L3 of the energy storage inductor is changed as a variable parameter. Furthermore, the input voltage V1 output from the direct-current power supply is changed within 38 V to 180 V according to the value of an inductance Li of the energy storage inductor. A smoothing capacitor having a capacitance C4 is connected in parallel to the direct-current power supply. An inductance L1 of the primary winding of the transformer is set to 74.4 μH and an inductance L2 of the secondary winding of the transformer is set to 1850 μH. A load capacitance of a capacitance C1 and a load resistance of a resistance R5 are connected to both ends of the secondary winding of the transformer. The value of the resistance R5, that is, 500 MΩ of the load resistance, is a value simulating the resistance of a torch/workpiece gap 24 (see FIG. 15). A capacitance C2 of the parasitic capacitance of the switching element is set to 45 pF. In a gate drive circuit of the switching element, a resistance R1 of the gate resistance is set to 1Ω. The other circuit elements illustrated in FIG. 6 are parasitic impedances, and their values are set to the values illustrated in FIG. 6. Simulation 1 assumes the transformer 2 to be suitable for the application of the high-voltage pulse generation circuit 100 of the first embodiment.
1. Input conditions
   i) Input voltage V1: The input voltage V1 was set so that the voltage Vds across both ends of the external capacitor was 1.2 kV in a state where the switching element was in a cut-off state.
   ii) Conduction time (predetermined time Tp): 2 μs
2. Output conditions
   i) Capacitance C1 of load capacitance: 10 pF
   ii) Resistance R5 of load resistance: 500 MΩ
3. Values of circuit parameters
   i) Voltage Vds across both ends of switching element in cut-off state: 1.2 kV
   ii) Capacitance C5 of external capacitor: Fixed to 2000 pF
   iii) Inductance L1 of primary winding of transformer: 74.4 μH (2 turn)
   iv) Inductance L2 of secondary winding of transformer: 1850 μH (10 turn)
   v) Cross-sectional area of transformer core: 100 mm²
   vi) Maximum saturation magnetic flux density Bmax of transformer: 1000 mT
4. Values of circuit parameter to be changed
   Inductance L3 of energy storage inductor: 1 μH, 2 μH, 3 μH, 4 μH, 4.5 μH, 5 μH, 8 μH, 10 μH, 37.2 μH, 74.4 μH
5. Determination conditions
   i) Output voltage Vout: Peak voltage is 6 kV or higher (times of turns ratio or higher)
   ii) Magnetic flux density B: Less than 1000 mT

### <Results>

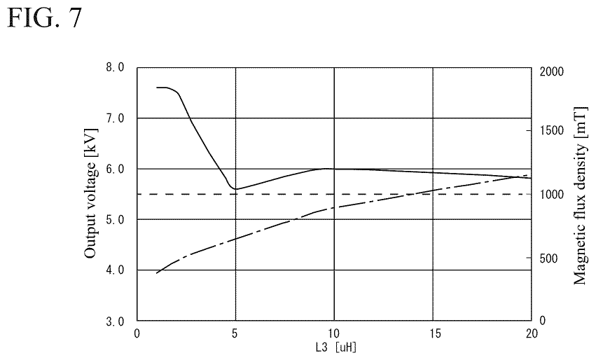

Table 1 and FIG. 7 below show the results of Simulation 1.

TABLE 1

| | Input | Composite | Output | |
|---|---|---|---|---|
| Inductance of energy | voltage | current | voltage | Magnetic flux |
| storage inductor [μH] | [V] | [A] | [kV] | density [mT] |
| 1 | 38 | 38 | 7.6 | 380 |
| 2 | 48 | 48 | 7.5 | 480 |
| 3 | 54 | 54 | 6.7 | 540 |
| 4 | 60 | 60 | 6.1 | 600 |
| 4.5 | 62 | 62 | 5.8 | 620 |
| 5 | 65 | 65 | 5.6 | 650 |
| 8 | 80 | 80 | 5.9 | 800 |
| 10 | 90 | 90 | 6.0 | 900 |
| 37.2 | 150 | 150 | 5.5 | 1500 |
| 74.4 | 180 | 180 | 5.0 | 1800 |

FIG. 7 shows results in a case where the energy storage inductor has an inductance L3 of 1 μH to 20 μH. FIG. 7 is a graph showing results of Simulation 1. In FIG. 7, the horizontal axis represents the inductance, the left vertical axis represents the output voltage Vout, and the right vertical axis represents the magnetic flux density B. In FIG. 7, the solid line indicates the output voltage Vout, and the alternate long and short dash line indicates the magnetic flux density B. The broken line indicates the maximum saturation magnetic flux density Bmax (1000 mT).

Referring to Table 1 and FIG. 7, the results of Simulation 1 are summarized as follows.
1. The output voltage Vout was 6 kV or higher at 5 points at which the inductance L3 of the energy storage inductor 3 had a value of 1.0 μH, 2.0 μH, 3.0 μH, 4.0 μH, or 10.0 μH.
2. At these 5 points, the transformer 2 has a magnetic flux density of 1000 mT or less, no magnetic saturation occurs, and no problem is observed.
3. The smaller the inductance L3 of the energy storage inductor 3 is, the smaller the input voltage V1 and the composite current Ix (input current) are.
4. From the above, a suitable value of the inductance L3 of the energy storage inductor 3 is 1 μH to 4 μH.
5. Referring to FIG. 7, in the energy storage inductor 3 such that the output voltage Vout is 6 kV or higher, the inductance L3 has an upper limit of 10 μH, in the energy storage inductor 3 such that the magnetic flux density B is not more than the maximum saturation magnetic flux density Bmax, the inductance L3 has a limit value of 14 μH, and in the primary winding W1 of the transformer 2, the inductance L1 has a value of 74.4 μH. Considering above, the inductance L3 of the energy storage inductor 3 is preferably 1/7 or less of the inductance L1 of the primary winding W1 of the transformer 2, more preferably 1/10 or less of the inductance L1 of the primary winding W1 of the transformer 2, and is preferably as small as possible.

### <Consideration>

1. If the inductance L3 of the energy storage inductor 3 is reduced, the input voltage V1 can be reduced, and thus a higher voltage can be applied between the windings of the transformer 2 (see Table 1). Therefore, conversely, if the inductance L3 is increased, the output voltage Vout is decreased.

For example, in a case where the inductance L3 of the energy storage inductor 3 is 2 μH, the input voltage V1 is 48 V, and the drain-source voltage Vds of the switching element 4 is 1.2 kV. Therefore, the primary-side voltage of the transformer 2 is 1.2 kV−48 V=1152 V, and the output voltage Vout is 1152 V×5=5.76 kV.

In a case where the inductance L3 of the energy storage inductor 3 is 37.2 H, the input voltage V1 is 150 V, and the drain-source voltage Vds of the switching element 4 is 1.2 kV. Therefore, the primary-side voltage of the transformer 2 is 1.2 kV−150 V=1050 V, and the output voltage Vout is 1050 V×5=5.25 kV. As described above, when the input voltage V1 is sufficiently lower than the drain-source voltage Vds, the input voltage V1 is substantially negligible, but when the input voltage is high, the input voltage V1 affects the output voltage Vout.

2. The reason why the output voltage Vout is higher by a factor of more than the turns ratio n is considered to be that a condition is satisfied in which, for example, the phase of the drain-source voltage (voltage across both ends of the external capacitor 5) Vds coincides with the phase of the output voltage Vout. For example, resonance of the external capacitor 5 with the energy storage inductor 3 is conceivable, and it is conceivable that this resonance overlaps with resonance of the energy storage inductor 3 with the load capacitance Co, the stray capacitance between the windings of the transformer 2, or the like.

3. For using a semiconductor element as the switching element 4, there is a constraint that, for example, in the case of using a semiconductor element having a rated current of 50 A, the energy storage inductor 3 to be used is required to have an inductance L3 of 2 μH or less.

### <<Simulation 2>>

Next, Simulation 2 will be described for examination of a suitable capacitance of the external capacitor 5.

### <Circuit>

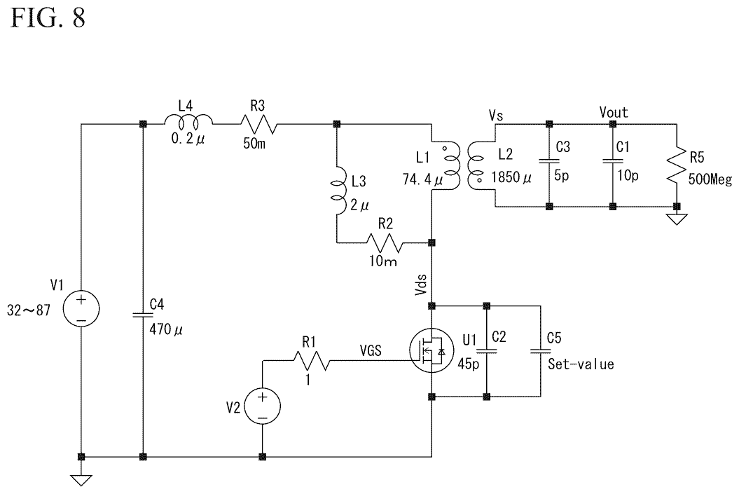

FIG. 8 is a circuit diagram illustrating a circuit configuration in Simulation 2, for the high-voltage pulse generation circuit 100 of the first embodiment, for observation of a change in the output voltage Vout in the case of changing the capacitance of the external capacitor 5. In this circuit diagram, a symbol attached to a circuit element represents the voltage, the resistance, the inductance, or the capacitance, and the number represents its value. Simulation 2 assumes the transformer that is assumed in Simulation 1.

Referring to FIG. 8, in the circuit of Simulation 2, the value “Set-value” of the capacitance C5 of the external capacitor is changed as a variable parameter. Furthermore, the input voltage V1 output from the direct-current power supply is changed within 32 V to 87 V according to the value of the capacitance C5 of the external capacitor. Other than the above, the circuit configuration is the same as that of the circuit in Simulation 1 in FIG. 6, and description of the same circuit configuration will be omitted.

### <Simulation Conditions>

1. Input conditions
   i) Input voltage V1: The input voltage V1 was set so that the voltage Vds across both ends of the external capacitor was 1.2 kV in a state where the switching element was in a cut-off state.
   ii) Conduction time (predetermined time Tp): 2 μs
2. Output conditions
   i) Capacitance C1 of load capacitance: 10 pF
   ii) Resistance R5 of load resistance: 500 MΩ
3. Values of circuit parameters
   i) Voltage Vds across both ends of switching element in cut-off state: 1.2 kV
   ii) Inductance L3 of energy storage inductor: Fixed to 2 μH
   iii) Inductance L1 of primary winding of transformer: 74.4 μH (2 turn)
   iv) Inductance L2 of secondary winding of transformer: 1850 μH (10 turn)
   v) Cross-sectional area of transformer core: 100 mm²
   vi) Maximum saturation magnetic flux density Bmax of transformer: 1000 mT
   vii) Rated current of switching element: 50 A
4. Values of circuit parameter to be changed
   Capacitance C5 of external capacitor: 0 pF (none), 250 pF, 500 pF, 750 pF, 1000 pF, 1500 pF, 2000 pF, 3000 pF, 3500 pF, 4000 pF, 5000 pF, 10,000 pF
5. Determination conditions
   i) Output voltage Vout: Peak voltage is 6 kV or higher
   ii) Magnetic flux density B: Less than 1000 mT
   iii) Composite current Ix: 50 A or less

### <Results>

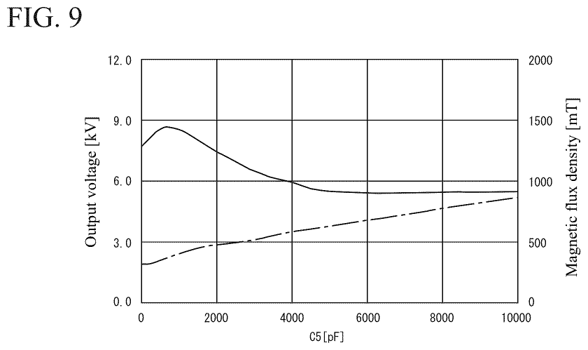

Table 2 and FIG. 9 show the results of Simulation 2.

TABLE 2

| | Input | Composite | Output | |
|---|---|---|---|---|
| Capacitance C5 of | voltage | current | voltage | Magnetic flux |
| external capacitor [pF] | [V] | [A] | [kV] | density [mT] |
| 0 | 32 | 32 | 7.7 | 320 |
| 250 | 32 | 32 | 8.2 | 320 |
| 500 | 35 | 35 | 8.6 | 350 |
| 750 | 38 | 38 | 8.7 | 380 |
| 1000 | 41 | 41 | 8.6 | 410 |
| 1500 | 45 | 45 | 8.1 | 450 |
| 2000 | 48 | 48 | 7.5 | 480 |
| 3000 | 52 | 52 | 6.5 | 520 |
| 3500 | 56 | 56 | 6.2 | 560 |
| 4000 | 59 | 59 | 6.0 | 590 |
| 5000 | 64 | 64 | 5.5 | 640 |
| 10000 | 87 | 87 | 5.5 | 870 |

FIG. 9 is a graph showing results of Simulation 2. In FIG. 9, the horizontal axis represents the capacitance, the left vertical axis represents the output voltage Vout, and the right vertical axis represents the magnetic flux density B. In FIG. 9, the solid line indicates the output voltage Vout, and the alternate long and short dash line indicates the magnetic flux density B. The broken line indicates the maximum saturation magnetic flux density Bmax (1000 mT). The vertical axis represents the output voltage Vout.

Referring to Table 2 and FIG. 9, the results of Simulation 2 are summarized as follows.

1. In the external capacitor 5 such that the output voltage Vout was 6 kV or higher, the capacitance was 0 pF to 4000 pF.

2. In a case where the capacitance of the external capacitor 5 is 0 pF to 4000 pF, the magnetic flux density is 1000 mT or less, no magnetic saturation occurs, and no problem is observed.

3. In a case where the composite current Ix (input current) is 50 A or less, the capacitance of the external capacitor 5 is 2000 pF or less.

4. From the above, a suitable capacitance of the external capacitor 5 is 0 pF to 2000 pF.

### <Consideration>

1. If the capacitor capacitance C5 of the external capacitor 5 is reduced, the input voltage V1 can be reduced, and thus a higher voltage can be applied between the windings of the transformer 2 (see Table 2). Therefore, conversely, if the capacitance C5 of the external capacitor 5 is increased, the output voltage Vout is decreased.

For example, in a case where the capacitance C5 of the external capacitor 5 is 2000 pF, the input voltage V1 is 48 V, and the drain-source voltage Vds of the switching element 4 is 1.2 kV. Therefore, the primary-side voltage of the transformer 2 is 1.2 kV−48 V=1152 V, and the output voltage Vout is 1152 V×5=5.76 kV.

In a case where the capacitance C5 of the external capacitor 5 is 10000 pF, the input voltage V1 is 87 V, and the drain-source voltage Vds of the switching element 4 is 1.2 kV. Therefore, the primary-side voltage of the transformer 2 is 1.2 kV−87 V=1113 V, and the output voltage Vout is 1113 V×5=5.565 kV.

As described above, when the input voltage V1 is sufficiently lower than the drain-source voltage Vds, the input voltage V1 is substantially negligible, but when the input voltage is high, the input voltage V1 affects the output voltage Vout.

2. The reason why the output voltage Vout is higher by a factor of more than the turns ratio n is considered to be that a condition is satisfied in which, for example, the phase of the drain-source voltage (voltage across both ends of the external capacitor 5) Vds coincides with the phase of the output voltage Vout. For example, resonance of the external capacitor 5 with the energy storage inductor 3 is conceivable, and it is conceivable that this resonance overlaps with resonance of the energy storage inductor 3 with the load capacitance, the stray capacitance between the windings of the transformer 2, or the like.

### <<Simulation 3>>

Next, Simulation 3 will be described for examination of the uniqueness of providing the external capacitor 5 in the high-voltage pulse generation circuit 100. The uniqueness herein means a configuration in which the capacitance C5 of the external capacitor 5 is set according to the capacitance C1 of the load capacitance Co and thus capacitive energy of the external capacitor 5 is temporarily obtained from the inductive energy of the energy storage inductor 3 to ensure sufficient energy at the time of pulse generation at both ends of the primary winding W1 of the transformer 2.

### <Circuit>

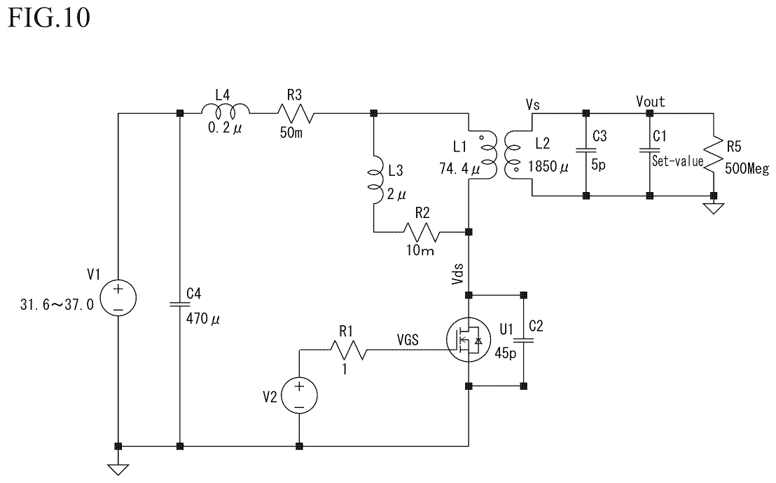

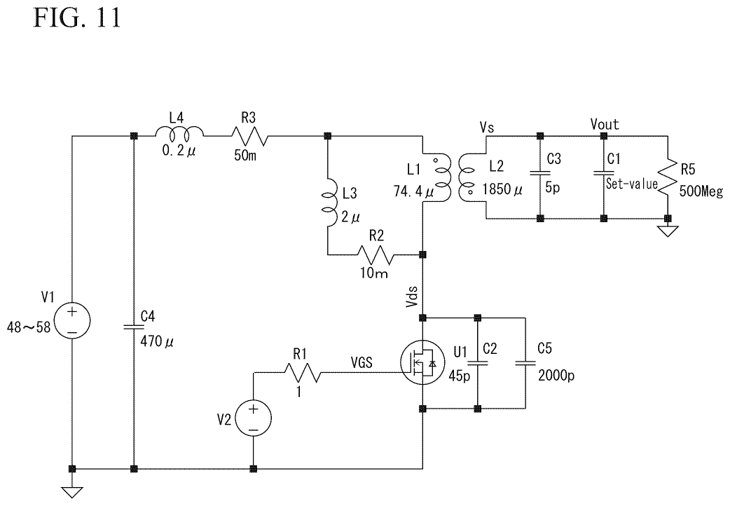

FIG. 10 is a circuit diagram illustrating a circuit configuration in Simulation 3, for the high-voltage pulse generation circuit, for observation of a change in the output voltage Vout in the case of changing the capacitance C1 of the load capacitance Co without the external capacitor 5. FIG. 11 is a circuit diagram illustrating a circuit configuration in Simulation 3, for the high-voltage pulse generation circuit, for observation of a change in the output voltage Vout in the case of changing the capacitance C1 of the load capacitance Co with the external capacitor 5. In these circuit diagrams, a symbol attached to a circuit element represents the voltage, the resistance, the inductance, or the capacitance, and the number represents its value. Simulation 3 assumes the transformer that is assumed in Simulation 1.

Referring to FIG. 10, the circuit in FIG. 10 does not include external capacitor. The value “Set-value” of the capacitance C1 of the load capacitance Co is changed as a variable parameter. Furthermore, the input voltage V1 output from the direct-current power supply is changed within 31.6 V to 37.0 V according to the value of the capacitance C1 of the load capacitance Co. Other than the above, the circuit configuration is the same as that of the circuit in Simulation 1 in FIG. 6, and description of the same circuit configuration will be omitted.

Referring to FIG. 11, the circuit in FIG. 11 includes the external capacitor 5. Other than the above, the circuit configuration is the same as that of the circuit in FIG. 10.

### <Simulation Conditions>

1. Input conditions
   i) Input voltage V1: The input voltage V1 was set so that the voltage Vds across both ends of the external capacitor was 1.2 kV in a state where the switching element was in a cut-off state.
   ii) Conduction time (predetermined time Tp): 2 μs
2. Output conditions
   i) Capacitance C5 of external capacitor: 0 pF or 2000 pF
   ii) Resistance R5 of load resistance: 500 MΩ
3. Values of circuit parameters
   i) Voltage Vds across both ends of switching element in cut-off state: 1.2 kV
   ii) Inductance L3 of energy storage inductor: Fixed to 2 μH
   iii) Inductance L1 of primary winding of transformer: 74.4 μH (2 turn)
   iv) Inductance L2 of secondary winding of transformer: 1850 μH (10 turn)
   v) Cross-sectional area of transformer core: 100 mm²
   vi) Maximum saturation magnetic flux density Bmax of transformer: 1000 mT
4. Values of circuit parameter to be changed
   Capacitance C1 of load capacitance: 10 pF, 100 pF, 200 pF, 300 pF, 400 pF, 500 pF
5. Determination conditions
   Effects are compared between the case where the external capacitor is not included and the case where the capacitance C5 of the external capacitor is 2000 pF.

### <Results>

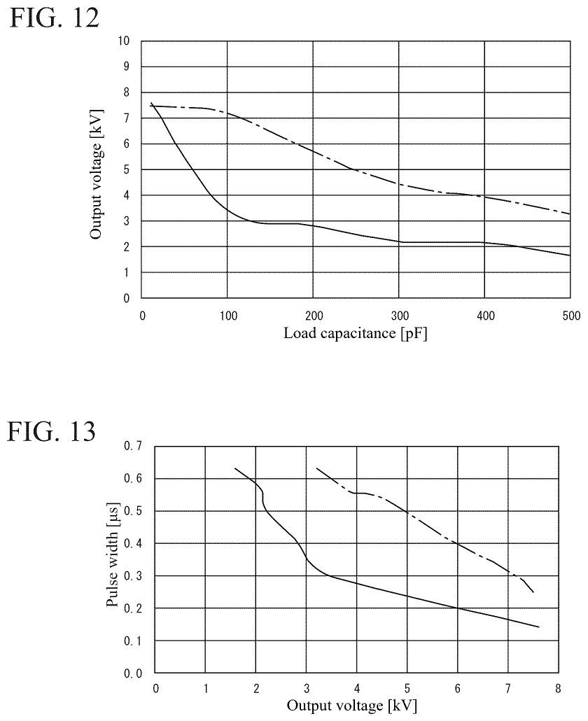

Table 3 and FIGS. 12 to 14 show the results of Simulation 3.
{External capacitor: absent}

TABLE 3

| Load | Input | Composite | Output | Pulse | |
|---|---|---|---|---|---|
| capacitance | voltage | current | voltage | width | Magnetic flux |
| [pF] | [V] | [A] | [kV] | [μs] | density [mT] |
| 10 | 31.6 | 29.0 | 7.6 | 0.1 | 316 |
| 100 | 37.0 | 33.8 | 3.4 | 0.3 | 370 |
| 200 | 40.0 | 36.1 | 2.8 | 0.4 | 400 |
| 300 | 38.0 | 34.0 | 2.2 | 0.5 | 380 |
| 400 | 40.8 | 36.9 | 2.1 | 0.6 | 408 |
| 500 | 37.0 | 35.8 | 1.6 | 0.6 | 370 |

{External capacitor: 2000 pF}

TABLE 4

| Load | Input | Composite | Output | Pulse | |
|---|---|---|---|---|---|
| capacitance | voltage | current | voltage | width | Magnetic flux |
| [pF] | [V] | [A] | [kV] | [μs] | density [mT] |
| 10 | 48.0 | 43.4 | 7.5 | 0.2 | 480 |
| 100 | 59.0 | 53.6 | 7.2 | 0.3 | 590 |
| 200 | 63.0 | 56.8 | 5.6 | 0.4 | 630 |
| 300 | 61.0 | 54.3 | 4.4 | 0.5 | 610 |
| 400 | 64.0 | 57.9 | 3.9 | 0.6 | 640 |
| 500 | 58.0 | 56.8 | 3.2 | 0.6 | 580 |

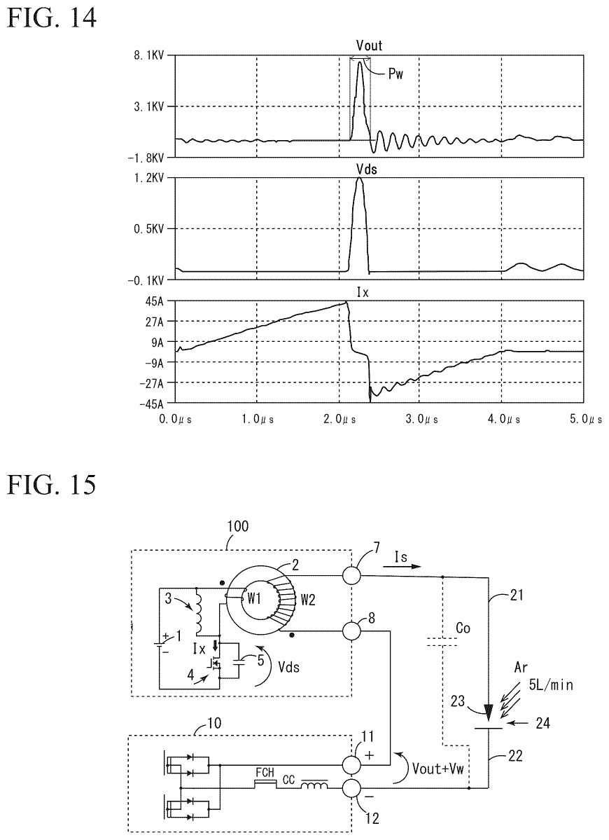

FIG. 12 is a graph showing a change in the output voltage Vout with respect to a change in the capacitance C1 of the load capacitance Co in Simulation 3. In FIG. 12, the horizontal axis represents the capacitance C1 of the load capacitance Co, and the vertical axis represents the output voltage Vout. FIG. 13 is a graph showing a change in a pulse width Pw with respect to a change in the output voltage Vout in Simulation 3. In FIG. 13, the horizontal axis represents the output voltage Vout, and the vertical axis represents the pulse width Pw. In FIGS. 12 and 13, the solid line indicates a case where the external capacitor is not included, and the alternate long and short dash line indicates a case where the external capacitor is included. FIG. 14 is a graph showing changes in the output voltage Vout, the drain-source voltage Vds of the switching element 4, and the composite current Ix in a case where, in Simulation 3, the capacitance C5 of the external capacitor 5 is 2000 pF and the capacitance C1 of the load capacitance Co is 10 pF.

First, the definitions of the pulse width Pw and the output voltage Vout will be described. Referring to FIG. 14, the upper waveform diagram illustrates the waveform of the output voltage Vout, the middle waveform diagram illustrates the waveform of the drain-source voltage Vds, and the lower waveform diagram illustrates the waveform of the composite current Ix. According to these waveform diagrams, in response to the fall of the composite current Ix, the single pulsed drain-source voltage Vds is generated, and the pulsed output voltage Vout is generated that includes a damped wave packet. Here, as illustrated in the upper waveform diagram, the pulse width of the output voltage Vout is defined as the time interval between the zero cross point at the start of the rise of the first wave and the zero cross point at the end of the fall of the first wave. The voltage value of the output voltage Vout is defined as the peak value of the first wave.

Referring to Tables 3 and 4 and FIGS. 12 and 13, the results of Simulation 3 are summarized as follows.

1. As is clear from FIG. 12, as the capacitance C1 of the load capacitance Co increases, the output voltage Vout decreases. In a case where the external capacitor 5 having a capacitance of 2000 pF was included, the output voltage Vout decreased more slowly than in a case where the external capacitor was not included, and thus an effect of the external capacitor 5 was confirmed. For example, in a case where the capacitance C1 of the load capacitance Co was 500 pF, the output voltage Vout was 1.6 kV without the external capacitor 5, and the output voltage Vout was 3.2 kV with the external capacitor 5 having a capacitance of 2000 pF.

2. As is clear from FIG. 13, the higher the output voltage Vout was, the narrower the pulse width Pw was, and the lower the output voltage Vout was, the wider the pulse width Pw was.

3. From the above, it has been found that the output voltage Vout can be increased by providing the external capacitor 5 except for a case where the capacitance C1 of the load capacitance Co is small.

### <Consideration>

1. In actual application, the external capacitor 5 is required, and a suitable capacitance of the external capacitor 5 is more than 0 pF and 2000 pF or less.

2. The capacitance of the external capacitor 5 is required to be adjusted to an appropriate capacitance according to the capacitance C1 of the load capacitance Co.

### [Design Method]

For reference, an example of a basic method of calculating a parameter in the design of the high-voltage pulse generation circuit 100 will be described below.

### {Method of Calculating Drain-Source Voltage Vds of Switching Element 4}

Immediately after the switching element 4 is brought into a cut-off state, LC resonance of the energy storage inductor 3 with the capacitor capacitance, such as the parasitic capacitances of the external capacitor 5 and the switching element 4, occurs. The capacitance of the external capacitor 5 is much larger than the other capacitor capacitances, and therefore only the capacitance of the external capacitor 5 is treated as the capacitor capacitance. Then, the resonance frequency fo can be determined with the following equation.

$${f}_{0} = \frac{1}{2 π \sqrt{{L}_{3} {C}_{5}}} [ Hz ] \qquad [ Equation 1 ]$$

When LC resonance occurs, the inductive energy stored in the energy storage inductor 3 transfers to the external capacitor 5, and a voltage is generated in the external capacitor 5. At this time, the rise time can be determined with the following equation.

### [Equation 2]

$${t}_{r} \approx \frac{1}{4 {f}_{0}} [ sec ] \qquad [ Equation 2 ]$$

The drain-source voltage Vds applied to both ends of the switching element 4 can be determined with the following two equations.

$$\frac{1}{2} {L}_{3} {I}_{x}^{2} = \frac{1}{2} {C}_{5} {V}_{DS}^{2} \qquad [ Equation 3 ]$$

$${V}_{DS} = {I}_{x} \sqrt{\frac{{L}_{3}}{{C}_{5}}} [ V ] \qquad [ Equation 4 ]$$

### {Method of Calculating Ix}

The current that can flow through the energy storage inductor 3 can be determined with the following equation. The input voltage is represented by Vin (input voltage V1), and the conduction time of the switching element 4 is represented by Ton (predetermined time Tp).

$${I}_{x} = \frac{{V}_{in} {T}_{on}}{{L}_{3}} [ A ] \qquad [ Equation 5 ]$$

In the high-voltage pulse generation circuit 100, it is important that the inductance L3 of the energy storage inductor 3 is small, and therefore the current value of the composite current Ix can be approximately set by any combination of the input voltage Vin and the conduction time Ton, ignoring the inductance L1 of the primary winding W1 of the transformer 2, as in the above equation.

### [Action Effect]

As is clear from the above description, according to the high-voltage pulse generation circuit 100 of the first embodiment, when the control circuit 6 keeps the switching element 4 in conduction for the predetermined time Tp and then brings the switching element 4 into a cut-off state, inductive energy (magnetic energy) is stored in the energy storage inductor 3 while the switching element 4 is kept in a conductive state. Then, when the switching element 4 is brought into a cut-off state, the direct-current voltage of the direct-current power supply 1 is applied to the energy storage inductor 3, the external capacitor 5 and the parasitic capacitances of the switching element 4, and thus LC resonance occurs. Thereby, a sinusoidal pulse voltage is generated at both ends of the external capacitor 5 and the parasitic capacitances of the switching element 4. The sinusoidal pulse voltage is applied to the primary winding W1 of the transformer 2, and the secondary winding W2 of the transformer 2 outputs a sinusoidal pulse voltage corresponding to the turns ratio n.

In this process, the transformer 2 mainly functions as an element that is nearly an ideal transformer rather than as an element that stores the inductive energy, so that even if the secondary winding W2 has a large inductance, the inductance does not inhibit the release rate of the energy stored in the external capacitor 5. Furthermore, the peak of the pulsed voltage output from the secondary winding W2 of the transformer 2 can be increased by using the resonance of the energy storage inductor 3 with the external capacitor 5 and the load capacitance. As a result, the high-voltage pulse generation circuit 100 can be provided that is capable of achieving a high release rate of stored energy and obtaining a high-voltage peak.

### EXAMPLES

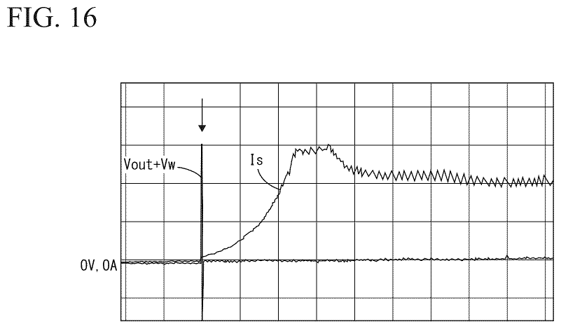

Next, an example of the high-voltage pulse generation circuit 100 of the first embodiment will be described. FIG. 15 is a circuit diagram illustrating an example of the high-voltage pulse generation circuit 100 of the first embodiment. In FIG. 15, the reference sign Co denotes the load capacitance. FIG. 16 is a graph showing the output voltage Vout (+an output voltage Vw of a welding machine 10) and the secondary-side current Is of the high-voltage pulse generation circuit 100 in the example of FIG. 15. In FIG. 16, the horizontal axis represents the elapsed time, and the vertical axis represents the output voltage Vout (+the output voltage Vw of the welding machine 10) and the secondary-side current Is of the high-voltage pulse generation circuit 100. One scale on the horizontal axis represents 50 μs, and one scale on the vertical axis represents 20 A and 2.5 kV.

Referring to FIG. 15, the welding machine 10 was connected between the positive output terminal 7 and the negative output terminal 8 of the high-voltage pulse generation circuit 100. Specifically, a positive output terminal 11 of the welding machine 10 was connected to the negative output terminal 8 of the high-voltage pulse generation circuit 100, and a negative output terminal 12 of the welding machine 10 was connected to a workpiece 22.

Meanwhile, a torch tip 23 was connected to the tip of a torch cable 21, and the base end of the torch cable 21 was connected to the positive output terminal 7 of the high-voltage pulse generation circuit 100.

The torch/workpiece gap 24 is present between the workpiece 22 and the torch tip 23. The torch cable 21 had a length of about 2.5 m. The distance of the torch/workpiece gap 24 was about 2 mm.

With such connections, a circuit was configured in which the output voltage Vout of the high-voltage pulse generation circuit 100 was superimposed on the output voltage Vw of the welding machine 10.

The torch/workpiece gap 24 was supplied with 5 liters of an argon (Ar) gas per second, and discharge in an argon atmosphere was performed instead of complete aerial discharge. The peak voltage of the output voltage Vout of the high-voltage pulse generation circuit 100 was set to about 10 kV.

Referring to FIG. 16, when start of the high-voltage pulse generation circuit 100 caused discharge (arrow) at about 10 kV in the torch/workpiece gap 24, a current flowed through the torch/workpiece gap 24 by the welding machine 10, and thus arc discharge started.

A main current (welding current) of about 80 A by the welding machine 10 flowed as the secondary-side current Is through the secondary winding of the transformer 2.

Thus, it has been demonstrated that the high-voltage pulse generation circuit 100 of the first embodiment can be applied to the welding machine 10.

### Second Embodiment

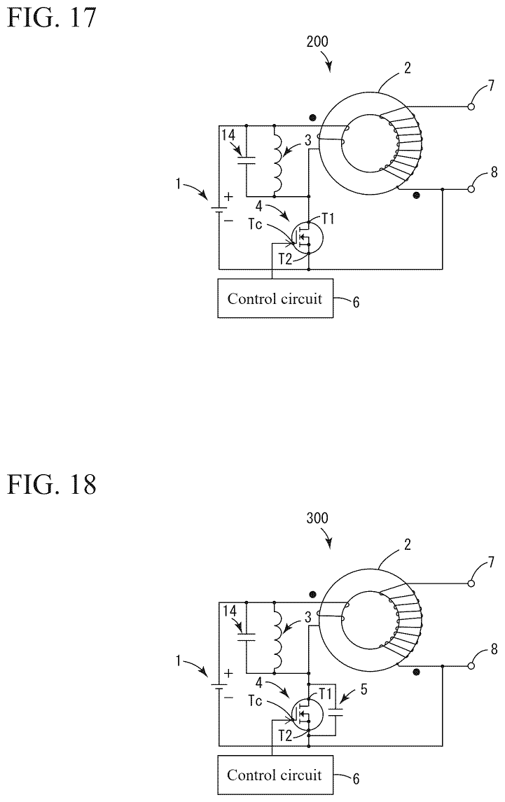

FIG. 17 is a circuit diagram illustrating an example of a configuration of a high-voltage pulse generation circuit 200 according to a second embodiment of the present disclosure.

Referring to FIG. 17, in the high-voltage pulse generation circuit 200 of the second embodiment, an external capacitor 14 is connected in parallel to an energy storage inductor 3, and an external capacitor is not connected to both ends of a switching element 4. Other than the above, the configuration is the same as that of the high-voltage pulse generation circuit 100 of the first embodiment.

In the high-voltage pulse generation circuit 200 configured as described above, a pulsed voltage is generated across both ends of the energy storage inductor 3 at a moment when the switching element 4 is brought into a cut-off state after being kept in conduction for the predetermined time Tp. Then, the external capacitor 14 is charged by the pulsed voltage by parallel LC resonance, and the inductive energy stored in the energy storage inductor 3 transfers to the external capacitor 14. Thus, a pulsed voltage corresponding to the pulsed voltage generated at both ends of the energy storage inductor 3 appears at both ends of the external capacitor 14, and is input to the primary winding W1 of the transformer 2. Then, the output voltage Vout of a high-voltage pulse having a voltage higher by a factor of the turns ratio n than the pulsed voltage is output from both ends of the secondary winding W2 of the transformer 2.

Therefore, like the high-voltage pulse generation circuit 100 of the first embodiment, the high-voltage pulse generation circuit 200 according to the second embodiment as described above can also provide a high-voltage pulse generation circuit that is capable of achieving a high release rate of stored energy and obtaining a high-voltage peak.

### Third Embodiment

FIG. 18 is a circuit diagram illustrating an example of a configuration of a high-voltage pulse generation circuit 300 according to a third embodiment of the present disclosure.

Referring to FIG. 18, in the high-voltage pulse generation circuit 300 of the third embodiment, in addition to an external capacitor 5 connected in parallel to a switching element 4, an external capacitor 14 is connected in parallel to an energy storage inductor 3. Other than the above, the configuration is the same as that of the high-voltage pulse generation circuit 100 of the first embodiment.

In the high-voltage pulse generation circuit 300 configured as described above, a pulsed voltage is generated across both ends of the energy storage inductor 3 at a moment when the switching element 4 is brought into a cut-off state after being kept in conduction for the predetermined time Tp. Then, the external capacitor 14 and the external capacitor 5 are charged by the pulsed voltage by LC resonance, and the inductive energy stored in the energy storage inductor 3 transfers to the external capacitor 14 and the external capacitor 5. Thus, a pulsed voltage corresponding to the pulsed voltage generated at both ends of the energy storage inductor 3 appears at both ends of the external capacitor 14 and the external capacitor 5, and is input to the primary winding W1 of the transformer 2. Then, the output voltage Vout of a high-voltage pulse having a voltage higher by a factor of the turns ratio n than the pulsed voltage is output from both ends of the secondary winding W2 of the transformer 2.

Therefore, like the high-voltage pulse generation circuit 100 of the first embodiment, the high-voltage pulse generation circuit 300 according to the third embodiment as described above can also provide a high-voltage pulse generation circuit that is capable of achieving a high release rate of stored energy and obtaining a high-voltage peak.

From the above description, many modifications and other embodiments are apparent to those skilled in the art. Therefore, the above description is to be interpreted only as an example.

The high-voltage pulse generation circuit of the present invention is useful as a high-voltage pulse generation circuit that is capable of achieving a high release rate of stored energy and obtaining a high-voltage peak.

What is claimed is:

1. A high-voltage pulse generation circuit comprising:
a direct-current power supply for outputting a direct-current voltage;
a transformer including a primary winding having one end connected to a positive terminal of the direct-current power supply;
an energy storage inductor connected across both ends of the primary winding of the transformer;
a switching element including one main terminal connected to another end of the primary winding of the transformer, the switching element including another main terminal connected to a negative terminal of the direct-current power supply;
an external capacitor connected across both ends of the switching element, connected across the both ends of the primary winding, or connected across the both ends of the switching element and across the both ends of the primary winding; and
a control circuit configured to keep the switching element in conduction for a predetermined time and then bring the switching element into a cut-off state.

2. The high-voltage pulse generation circuit according to claim 1, wherein the control circuit is configured to input a digital control signal to a control terminal of the switching element, the digital control signal including a predetermined pulse to keep the switching element in conduction for a predetermined time and then bring the switching element into a cut-off state.

3. The high-voltage pulse generation circuit according to claim 2, wherein the control circuit is configured to input the digital control signal to the control terminal of the switching element, the digital control signal including a plurality of the predetermined pulses at a predetermined time interval.

4. The high-voltage pulse generation circuit according to claim 1, wherein the energy storage inductor has an inductance of 1/7 or less of an inductance of the primary winding of the transformer.

5. The high-voltage pulse generation circuit according to claim 1, wherein the energy storage inductor has an inductance of 1/10 or less of an inductance of the primary winding of the transformer.

6. The high-voltage pulse generation circuit according to claim 1, wherein the energy storage inductor has an inductance of 1 μH or more and 4 μH or less.

7. The high-voltage pulse generation circuit according to claim 1, wherein the external capacitor has a capacitance of more than 0 pF and 2000 pF or less.
